(19) United States
(12) Patent Application Publication
(10) Pub. No.: US 2025/0046621 A1
(43) Pub. Date: Feb. 6, 2025

(54) IC PACKAGE WITH IMMERSION TIN ON FLANK

(71) Applicant: TEXAS INSTRUMENTS INCORPORATED, DALLAS, TX (US)

(72) Inventors: Nazila Dadvand, Santa Clara, CA (US); Xuan Mo Li, Chengdu (CN); Huo Yun Duan, Chengdu (CN)

(21) Appl. No.: 18/362,635

(22) Filed: Jul. 31, 2023

(51) Int. Cl. H01L 21/48; H01L 21/683; H01L 23/495

(52) U.S. Cl. CPC H01L 21/4828; H01L 21/6835; H01L 23/49582; H01L 21/561; H01L 23/3121; H01L 24/48; H01L 2221/68331; H01L 2224/48091; H01L 2224/48245

(57) ABSTRACT

A method for forming integrated circuit (IC) packages includes mounting tape on a mold compound of a strip of flat no-leads IC packages. The method also includes sawing the mold compound of the strip of flat no-leads IC packages to form singulated IC packages mounted on the tape. The method further includes immersing the singulated IC packages in a bath of immersion tin to form immersion tin plating on a flank of leads of the singulated IC packages.

### TECHNICAL FIELD

This description relates to forming integrated circuit (IC) packages with immersion tin on a flank of leads.

### BACKGROUND

There are different integrated circuit (IC) package types available on the market that include conductive leads on the underside of the IC package for solder joints. Because the leads are not easily viewed or exposed, it is difficult to determine whether the IC package has been successfully soldered on to a printed circuit board (PCB). A wettable flank design exposes the leads at the sidewalls of the IC package which enables optical inspection of the soldering. However, the exposed leads are prone to oxidation and corrosion, making sidewall solder wetting difficult and reducing the shelf-life of the IC package.

### SUMMARY

A first example is related to a method for forming integrated circuit (IC) packages. The method includes mounting tape on a mold compound of a strip of flat no-leads IC packages. The method also includes sawing the mold compound of the strip of flat no-leads IC packages to form singulated IC packages mounted on the tape. The method further includes immersing the singulated IC packages in a bath of immersion tin to form immersion tin plating on a flank of leads of the singulated IC packages.

A second example relates to an IC package. The IC package includes a die mounted on a flat no-leads interconnect and a mold compound encapsulating the die on a top side of the flat no-leads interconnect. A flank of leads of the flat no-leads interconnect has an immersion tin plating that is greater than 2 micrometers thick.

### BRIEF DESCRIPTION OF THE DRAWINGS

FIG. 1 illustrates an example of a strip of flat no-leads integrated circuit (IC) packages.

FIG. 2 illustrates an example of a strip of flat no-leads IC packages mounted on tape.

FIG. 3 illustrates an example of singulated IC packages mounted on tape.

FIG. 4 illustrates an example of an immersion tin bath for singulated IC packages mounted on tape.

FIG. 5 illustrates an example of singulated IC packages having an immersion tin plating.

FIG. 6 illustrates an example process flow for utilizing the immersion tin bath.

FIG. 7 illustrates an example of wire bonding between a die and leads.

FIG. 8 illustrates a flowchart of an example method for forming IC packages.

FIG. 9 illustrates a flowchart of an example method for utilizing the immersion tin bath.

### DETAILED DESCRIPTION

This description relates to forming integrated circuit (IC) packages. Many IC packages include an interconnect (alternatively referred to as a leadframe) onto which one or more dies containing semiconductor devices are mounted and electrically attached. The interconnect(s) and die(s) are encapsulated within a mold compound forming a housing around the interconnect(s) and die(s). The interconnect(s) include a plurality of electrical contacts or leads that are exposed to an external environment to enable the device(s) within the housing to be electrically coupled with one or more other electrical components external to the housing.

Interconnect(s) with wettable flanks for IC packages, such as quad-flat no-leads (QFN) and dual-flat no-leads (DFN), do not have leads protruding from the housing. Instead, wettable flanks refer to non-protruding leads or contact lands of an interconnect. The wettable flanks are manufactured in a manner that promotes wetting of solder to the leads when mounted to a PCB. Wettable flanks enable the formation of a solder fillet that is able to be visually inspected (e.g., via automated optical inspection (AOI)) to verify an acceptable solder joint was formed between the lead and the PCB. Wetting is achieved by coating or plating the conductive material, such as copper, of the interconnect with a solderable metal that is different than the conductive material and offers increased wettability for solder (e.g., exhibits increased solderability). Example metals that have high degrees of solderability include nickel, palladium, tin, and gold.

In some examples, flat no-leads IC packages are fabricated in strips. During a singulation process, individual IC packages are cut from the strips by cutting through the interconnect to expose the internal copper material of the interconnect at the sidewall of the individual IC packages. At such locations, the exposed copper surface of the interconnect is a wettable flank that can be visually inspected but is subject to corrosion.

In the devices and methods described herein, the wettable flank is plated with an immersion tin plating that mitigates corrosion and protects the leads of the interconnects. The immersion tin plating is applied in an immersion tin bath that results in an immersion tin plating with a thickness greater than 2 micrometers on the wettable flank. The thickness of the immersion tin plating increases the shelf-life and reliability of the flat no-leads IC packages.

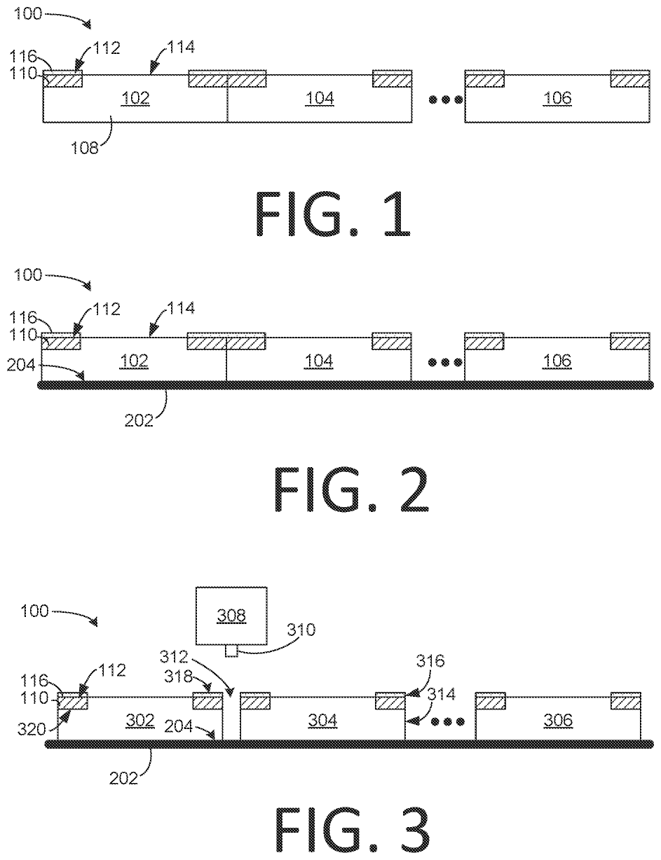

FIGS. 1-5 illustrate stages of a method for forming IC packages that include immersion tin on the flanks of the leads. For purposes of simplification, FIGS. 1-5 employ the same references numbers to denote the same structure. FIG. 1 illustrates a first stage of the method of forming the IC packages. In FIG. 1, an example strip 100 of flat no-leads IC packages including a first flat no-leads IC package 102, a second flat no-leads IC package 104, and a third flat no-leads IC package 106. The unsingulated flat no-leads IC packages 102, 104, 106 each include an interconnect electrically connected to a die encapsulated in a mold compound 108. The mold compound 108 encapsulates the die on a top side of the flat no-leads interconnect.

The components described with respect to one unsingulated flat no-leads IC packages, such as the first unsingulated flat no-leads IC package 102, are present in other unsingulated flat no-leads IC packages, such as the second unsingulated flat no-leads IC package 104 and the third unsingulated flat no-leads IC package 106, of the strip 100 and operate in a similar manner. For clarity, reference numbers identify components with respect to one unsingulated flat no-leads IC package. The strip 100 is an array of unsingulated flat no-leads IC packages that extend in a longitudinal direction and are coupled to each other by the mold compound 108. While a single row of flat no-leads IC packages extending in a longitudinal direction is described for clarity, in other examples, the strip 100 includes a plurality of rows flat no-leads IC packages.

The flat no-leads IC packages 102, 104, 106 are formed with interconnects of a conductive material and are associated with corresponding leads 110 formed of the conductive material. For example, the leads 110 of the flat no-leads interconnect are formed with copper. A first side 112 of the leads 110 is approximately flush with the mold compound 108 at a first surface 114 of the strip 100. The first surface 114 of the strip 100 refers to the surface that faces a PCB when a corresponding no-leads IC packages of the strip 100 is mounted (e.g., soldered) to the PCB. Stated differently, the first side of the leads 110 does not extend beyond the first surface 114 of the strip 100 in a lateral direction approximately orthogonal to the longitudinal direction.

The first side 112 of the leads 110 is coated with solderable metal layer 116 that extends past the first surface 114 of the strip 100 in the lateral direction. The solderable metal layer 116 provides a protective coating that prevents oxidation at the first side 112 of the leads 110. The solderable metal layer 116 is formed of a solderable metal material. Examples of the solderable metal material include various forms of nickel, palladium, tin, gold, etc. In the illustrated example, the leads 110 are formed of the conductive material, here copper (Cu), and the solderable metal layer 116 is formed of a solderable material, here matte tin (Sn). The solderable metal layer 116 is formed by applying the solderable metal material to the first side 112 of the leads 110 in a deposition process, such as electroplating that utilizes an electric current. The solderable metal layer 116 does not extend in the longitudinal direction over the mold compound 108.

FIG. 2 illustrates a second stage of the method of forming the IC packages. In FIG. 2, the strip 100 of flat no-leads IC packages 102, 104, 106, described above with respect to FIG. 1, is mounted on tape 202. The tape 202, such as an ultraviolet (UV) tape, is applied to a second surface 204 of the strip 100 opposite the first surface 114 of the strip 100. In some examples, the strip 100 and the tape 202 is positioned on a carrier, frame, or other suitable surface. The tape 202 supports the strip 100 during a singulation process. As one example, the tape 202 includes dicing markings that indicate locations where the strip 100 is to be cut during the singulation process.

FIG. 3 illustrates a third stage of the method of forming the IC packages. In FIG. 3, examples of singulated IC packages including a first singulated flat no-leads IC package 302, a second singulated flat no-leads IC package 304, and a third singulated flat no-leads IC package 306 are illustrated. The singulated flat no-leads IC packages 302, 304, 306 mounted on the tape 202 correspond to the unsingulated flat no-leads IC packages 102, 104, 106 of FIG. 1.

The singulation process utilizes a severing tool 308. For example, the severing tool 308 is a saw that includes a saw blade 310 configured to scribe, saw or dice through a height of the strip 100 in the lateral direction. The saw blade 310 travels a path from the first surface 114 to the second surface 204 through the strip 100 to the tape 202 without severing the tape 202. Because the singulation process does not sever the tape 202, the first singulated flat no-leads IC package 302, the second singulated flat no-leads IC package 304, and the third singulated flat no-leads IC package 306 remain supported by the strip 100 due to adhesion to the tape 202. In other examples, the severing tool 308 is laser-based or plasma-based.

The first singulated flat no-leads IC package 302, the second singulated flat no-leads IC package 304, and the third singulated flat no-leads IC package 306 are spaced apart from one another by trenches 312. The trenches 312 are voids that extend toward the second surface 204. By virtue of the singulation, the trenches 312 expose the copper leads 110 at sidewall surfaces 314 forming wettable flanks. Therefore, the bottom and the flank of the leads 110 are exposed.

The depth of the trenches 312 is defined in the lateral direction and varies depending on whether a solderable metal layer 116 is present on the first surface 114. For example, where the solderable metal layer 116 is present, the depth of the trench 312 extends from the third surface 318 to the second surface 204 of the strip 100. Where the solderable metal layer 116 is not present, the depth of the trench 312 extends from the first surface 114 to the second surface 204. Accordingly, the depth of the trenches 312 varies.

In some examples, the width of the trenches 312, defined in the longitudinal direction, is based on a predetermined separation distance between adjacent singulated flat no-leads IC packages. For example, the predetermined distance is set to greater than ten micrometers. In another example, the width of the trenches 312 is based on a profile of the severing tool 308 and/or the saw blade 310. In some examples, the width of the trenches 312 is variable having a first width at a first depth and a second width at a second depth. The first width and the second width satisfy the predetermined distance. Continuing the example from above, the first width may be greater or less than the second width, but both the first width and the second width are greater than ten micrometers.

The trenches 312 define sidewall surfaces 314 of the singulated flat no-leads IC packages 302, 304, 306. The sidewall surfaces 314 are approximately orthogonal to the first surface 114 and the second surface 204. The singulated flat no-leads IC packages 302, 304, 306 have corresponding leads 110 and solderable metal layers 116. As a result of the singulation process, a second side 316 of the leads 110 is exposed at the sidewall surfaces 314 of the singulated flat no-leads IC packages 302, 304, 306 thereby forming wettable flanks. In one example, the second side 316 of the leads 110 is approximately flush with the sidewall surfaces 314. In the illustrated example, the exposed second side 316 extends approximately orthogonally from the first side 112 of the leads 110. The second side 316 of the leads 110 extends from the first side 112 to a third side 320 of the leads 110. The third side 320 is opposite the first side 112 and proximate to the second surface 204. As one example, the solderable metal layer 116 is approximately twelve micrometers thick extending from the first side 112 to a third surface 318 in the lateral direction.

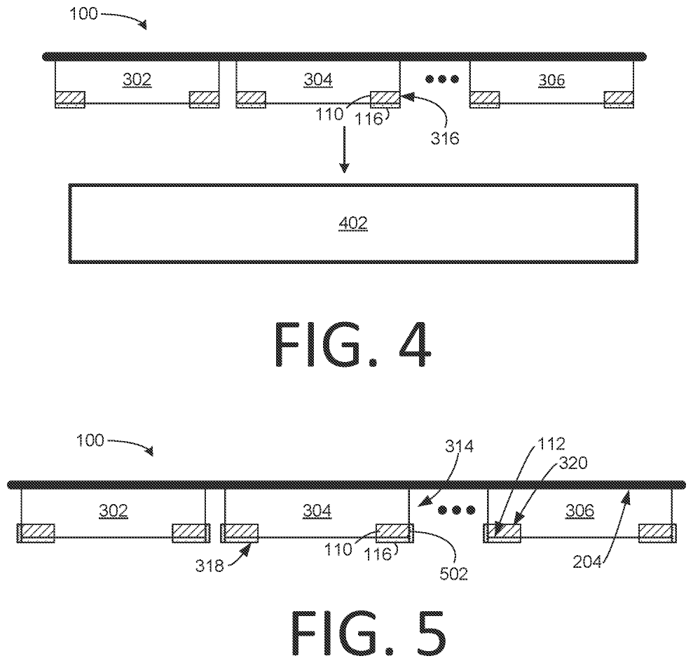

FIG. 4 illustrates a fourth stage of the method of forming the IC packages. In FIG. 4, the singulated IC packages 302, 304, 306 are immersed in an immersion tin bath 402. The immersion tin bath 402 coats the second side 316 of the leads 110 with a plating material utilizing a chemical reaction between the interconnect material and the immersion tin bath 402. In one example, the immersion tin bath 402 is the same as the solderable metal material of the solderable metal layer 116. In another example, the immersion tin bath 402 is different than the solderable metal material of the solderable metal layer 116. The immersion tin bath 402 includes various forms of tin. As one example, the immersion tin bath 402 comprises a solution of tin, tin salt, and an activator. While the immersion tin bath 402 is described with immersion tin, other suitable materials with similar properties may be used. Because matted tin plating of the solderable metal layer 116 is applied to the bottom of leads 110 of the strip 100 of flat no-leads IC packages prior to the dipping in the immersion tin bath 402, the immersion tin bath 402 is non-reactive to the solderable metal material of the solderable metal layer 116.

In some examples, the immersion tin bath 402 includes a shock generator and/or a vibrator. The shock generator is configured to apply a shock to the immersion tin bath 402 to release air bubbles in the immersion plating material. The vibrator is configured to apply vibration to the immersion tin bath 402 and or the strip 100 to loosen byproducts of the chemical reaction.

FIG. 5 illustrates a fifth stage of the method of forming the IC packages. In FIG. 5, the singulated IC packages 302, 304, 306 have immersion tin plating 502 from the immersion tin bath 402. The immersion tin plating 502 coats the second side 316 of the leads 110. The immersion tin plating 502 extends along the sidewall surfaces 314 from the third side 320 of the leads 110 to the first side 112 of the leads 110 in the lateral direction. In some examples, the immersion tin plating 502 additionally extends in the lateral direction from the third side 320 of the leads 110 past the first side 112 of the leads 110 so that the immersion tin plating 502 coats a portion of the sidewall surfaces 314 formed by the solderable metal layer 116. For example, the solderable metal layer 116 extends from the first surface 114 to the third surface 318 of the strip 100 distal from the second surface 204. The immersion tin plating 502 has a height that extends along the sidewall surfaces 314 from the third side 320 of the leads 110 to the third surface 318 of the strip 100. In one example, the immersion tin plating 502 has a height of at least 50 micrometers, in the lateral direction, adjacent the sidewall surfaces 314. As another example, the immersion tin plating 502 has a height of at least 100 micrometers.

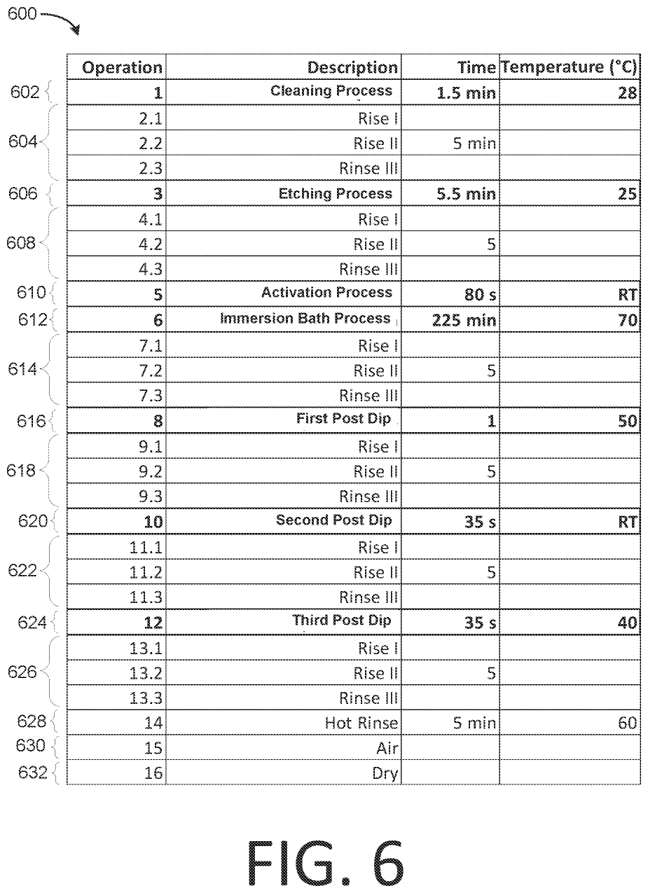

FIG. 6 illustrates an example process flow 600 of the immersion bath process, described above with respect to FIG. 4. At 602, a cleaning process is performed. In the cleaning process, a cleaning agent is applied to the strip 100 to remove contaminants from the strip 100 that have been encountered during the fabrication and/or singulation process. In one example, the cleaning agent is STANNA-Q ETCH. As one example, the cleaning process is performed for thirty seconds to two minutes at 20 to 40 degrees Celsius.

At 604, a first rinsing cycle is performed to remove the cleaning agent from the strip 100. The first rinsing cycle includes a number of rinsing operations. For example, the strip 100 undergoes a first rinse operation, a second rinse operation, and a third rinse operation. In one example, the rinsing operations are performed for one to ten minutes at approximately 20 degrees Celsius.

At 606, an etching process is performed to remove oxidation or defects by etching the exposed conductive material, here the copper interconnects, in particular, the second side of the leads 110. For example, the etching process includes applying an etching agent to the second side 316 of the leads 110. The etching agent removes burs in the second side 316 of the leads 110 caused by the singulation process or oxidation resulting from the conductive material at the second side 316 being exposed to the environment. The etching agent is, for example, STANNA-Q PROTECT. In one example, the etching process removes approximately 6 micrometers of the second side 316 of the leads 110. As one example, the etching process is performed for one to eleven minutes at 15 to 35 degrees Celsius.

At 608, a second rinsing cycle is performed to remove the etching agent. In some examples, the rinsing cycles are standardized. For example, the strip 100 undergoes a first rinse operation, a second rinse operation, and a third rinse operation performed for one to ten minutes at approximately 20 degrees Celsius during the second rinsing cycle similar to the first rinsing cycle.

At 610, in an activation process, the strip 100 is dipped in an activation chemical to prepare the second side 316 of the leads 110 for the immersion tin bath. The activation chemical is, for example, STANNA-Q DIP.

At 612, immersion of the strip 100 in an immersion bath of the immersion tin bath 402 is performed. In particular, the second side 316 of the leads 110 is submerged in the immersion tin bath. For example, at a first time in the immersion tin bath 402, the second side 316 of the leads 110 makes contact with the immersion tin bath at a depth corresponding to the first side 112 of the leads 110. At a second time after the first time in the immersion tin bath 402, the second side 316 of the leads 110 makes contact with immersion tin bath at a depth corresponding to the third side 320 of the leads 110. The immersion tin bath is, for example, STANNA-Q2. As one example, the immersion of the strip 100 is performed for 150 minutes to 4 hours at a temperature of 50 to 90 degrees Celsius.

In one example, the immersion tin bath 402 includes shocking the immersion tin bath in response to immersing the strip 100 in the immersion tin bath. Additionally or alternatively, the immersion tin bath 402 includes vibrating the immersion tin bath when the strip 100 is submerged.

At 614, a third rinsing cycle is performed. For example, the strip 100 undergoes a first rinse operation, a second rinse operation, and a third rinse operation performed for one to ten minutes at approximately 20 degrees Celsius during the third rinsing cycle. The rinsing cycles are performed before and after the immersion tin bath.

At 616, the strip 100 is dipped in first dip chemical to prepare the strip 100 for a second dip chemical in a first post-dip process. The first dip chemical is, for example, IONIX SF 8. As one example, the first post-dip process is performed for 30 seconds to 2 minutes at 40 to 60 degrees Celsius.

At 618, a fourth rinsing cycle is performed. For example, the strip 100 undergoes a first rinse operation, a second rinse operation, and a third rinse operation performed for one to ten minutes at approximately 20 degrees Celsius during the fourth rinsing cycle.

At 620, the strip 100 is dipped in the second dip chemical to prepare the strip 100 for a third dip chemical in a second post-dip process. The second dip chemical is, for example, PROTECTOSTAN PLUS 2. As one example, the second post-dip process is performed for 15 seconds to 1 minute at approximately 20 degrees Celsius.

At 622, a fifth rinsing cycle is performed. For example, the strip 100 undergoes a first rinse operation, a second rinse operation, and a third rinse operation performed for one to ten minutes at approximately 20 degrees Celsius during the fifth rinsing cycle.

At 624, the strip 100 is dipped in a third dip chemical that forms an anti-tarnish layer on the immersion tin plating 502 in a third post-dip process. In one example, the first dip chemical is the same as the third dip chemical. The third dip chemical is, for example, IONIX SF 8. The anti-tarnish layer protects the immersion tin plating 502. As one example, the third post-dip process is performed for 15 seconds to 1 minute at 20 to 60 degrees Celsius.

At 626, a sixth rinsing cycle is performed. For example, the strip 100 undergoes a first rinse operation, a second rinse operation, and a third rinse operation performed for one to ten minutes at approximately 20 degrees Celsius during the sixth rinsing cycle.

At 628, a hot rinse is performed to rinse the strip 100. For example, the hot rinse is performed for one to ten minutes at approximately 60 degrees Celsius. At 630, air is applied to the strip 100 and at 632, a drying process is performed.

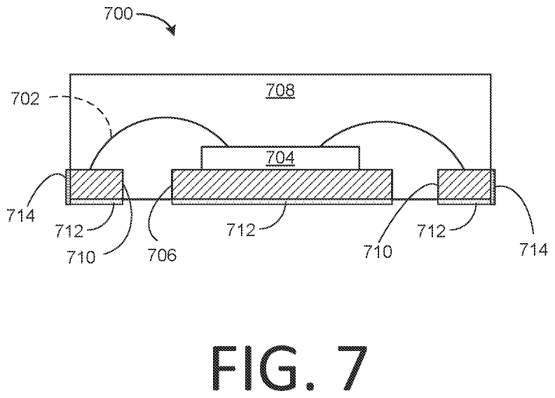

FIG. 7 illustrates an example of an IC package 700 with a wire bond connection 702 of a die 704 mounted on a die pad 706 encapsulated in a mold compound 708. The mold compound 708 encapsulates the die 704 on a top side of the flat no-leads interconnect. In some examples, the IC package 700 is formed with the method described in FIGS. 1-5. The die pad 706 separates the leads 710 and the wire bond connection 702 forms an electrical connection between the die 704 and the leads 710.

A solderable metal layer 712 is applied to a first side of the leads 710. The solderable metal layer 712 is employable to implement the solderable metal layer 116 of FIG. 1. Additionally, the solderable metal layer 712 is applied to the die pad 706. In one example, the solderable metal layer 712 is a matte tin plating. Accordingly, a bottom side of the leads 710 of the IC package 700 has matted tin plating. An immersion tin plating 714 is applied to a second side of the leads 710 that is approximately orthogonal to the first side of the leads 710. The immersion tin plating 714 is employable to implement the immersion tin plating 502 of FIG. 5. As one example, a flank of leads have an immersion tin plating that is greater than 2 micrometers thick.

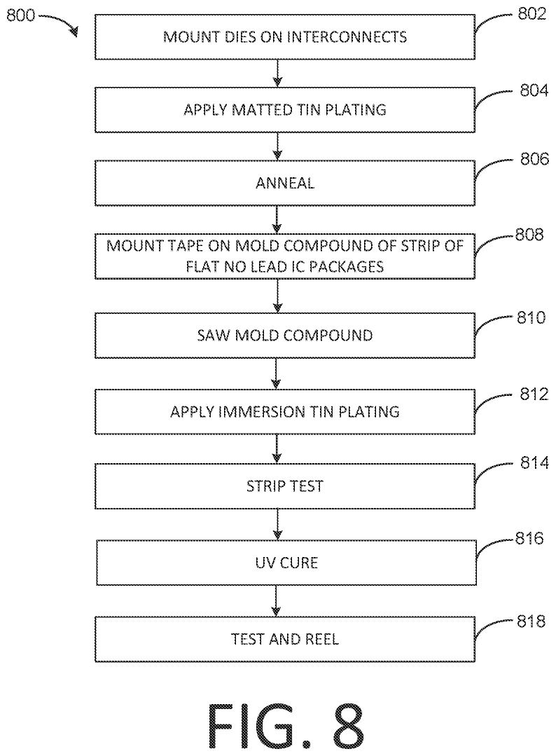

FIG. 8 illustrates a flowchart of an example method 800 for forming circuit IC packages, such as the IC package 700 of FIG. 7. At 802, dies are mounted on the array of interconnects of a strip, such as the strip 100 of FIG. 1. In some examples, a single die (e.g., the die 704 of FIG. 7) is mounted on an interconnect of the strip of interconnects. A first side of the leads, formed by the interconnect, is exposed at a first surface of a flat no-leads IC package.

At 804, a first side of the leads is coated with a solderable metal material, such as matte tin, to form the solderable material layer (e.g., the solderable metal layer 116 of FIG. 1, the solderable metal layer 712 of FIG. 7). As one example, the solderable metal material is applied using an electroplating process that utilizes an electric current to deposit the solderable metal material on the first side of the leads of the first flat no-leads IC package.

At 806, an anneal process is performed to heat the solderable material layer of the strip to approximately 150 degrees Celsius for about one hour. The anneal process reduces whiskering by releasing residual stress of the solderable material layer.

At 808, the strip 100 is applied to tape. At 810, a singulation process is performed that separates the flat no-leads IC packages from a strip, such as the strip 100 of FIG. 5. The singulation process cuts a mold compound and an interconnect associated with the leads. As a result of the singulation process, a second side of the leads is exposed to form the wettable flanks of the singulated flat no-leads IC packages. The second side of the leads is approximately orthogonal to the first side of the leads. Because the interconnect is encapsulated by the mold compound when the solderable material layers was applied to the first side of the leads, the exposed second side of the leads is not coated and the conductive material of the interconnect is exposed at the sidewall surfaces of the singulated flat no-leads IC package.

At 812, the second side of the leads is coated in an immersion plating material with an immersion tin bath 402 described with respect to FIG. 4. The immersion bath utilizes a chemical reaction between the conductive material of the interconnect and the immersion tin bath to coat the second side of the leads with the immersion tin material to form the immersion tin plating (e.g., immersion tin plating 502 of FIG. 5, the immersion tin plating 714 of FIG. 7). In some examples, an electric current is not applied to the immersion tin bath for plating. The immersion tin bath does not adhere to the mold compound 708. Accordingly, the immersion tin plating coats the second side of the leads does not extend past the leads. In one example, annealing is not performed after the immersion bath.

At 814, a strip test is performed on the singulated flat no-leads IC package. For example, the singulated flat no-leads IC packages, such as the first singulated flat no-leads IC package 302, the second singulated flat no-leads IC package 304, and the third singulated flat no-leads IC package 306 are tested in parallel.

At 816, a curing process is performed to release the singulated flat no-leads IC packages from the tape. As one example, the tape is an ultraviolet (UV) curable tape that when exposed to UV radiation in the curing process. At 818, a test and reel process is performed. Responsive to the curing, the adhesive of the tape is rendered ineffective. Accordingly, after the curing process, the singulated flat no-leads IC packages are removed from the tape and are packaged.

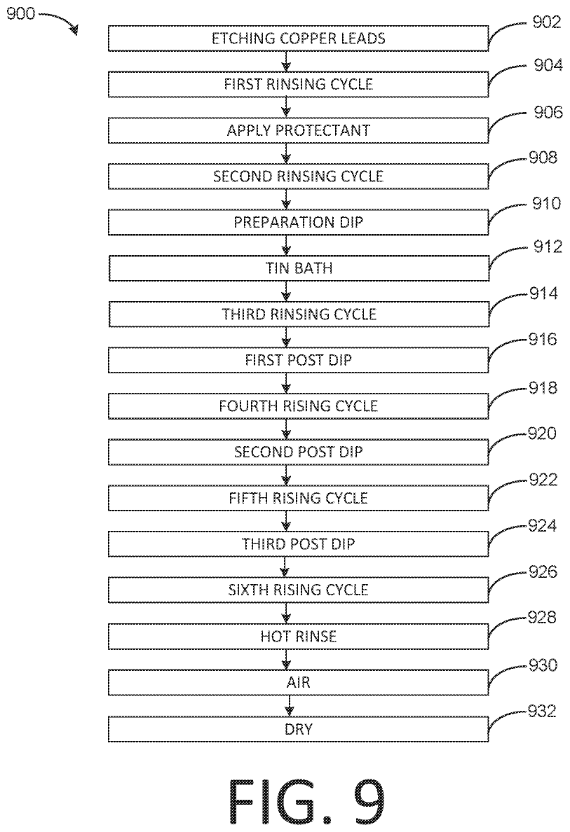

FIG. 9 illustrates a flowchart of an example method 900 that includes additional subprocesses of the method 800 at 812 for utilizing the immersion tin bath.

At 902, a cleaning process is performed. In the cleaning process, a cleaning agent is applied to the strip. For example, the cleaning process includes applying the cleaning agent to the wettable flanks formed by the exposed leads. As one example, the cleaning agent etches exposed copper of the copper interconnects that form the exposed leads.

At 904, a first rinsing cycle is performed after the etching to remove the cleaning agent from the strip.

At 906, a protectant is applied to the wettable flanks to protect exposed copper of the leads at a second side of an IC package from oxidation or defects.

At 908, a second rinsing cycle is performed to remove the protectant from the second side of the leads. At 910, the strip undergoes a preparation dip and is dipped in an activation chemical to prepare the second side of the leads for the immersion tin bath, such as the immersion tin bath 402 of FIG. 4. The activation chemical increases the reactivity between the conductive material and the immersion tin bath.

At 912, the strip is immersed in an immersion tin bath. In particular, the immersion includes dipping the singulated IC packages in the bath of immersion tin such that the etched exposed copper is submerged in the immersion tin. The second side of the leads is submerged in the immersion tin bath to form an immersion tin plating (e.g., immersion tin plating 502 of FIG. 5, the immersion tin plating 714 of FIG. 7). The thickness of the immersion tin plating is based on the chemical reaction between the conductive material and the solution of the immersion tin bath and is increased by greater reactivity. In one example, the immersion tin plating has a thickness, in the longitudinal direction, greater than 2 micrometers. In another example, the immersion tin plating has a thickness, in the longitudinal direction, greater than 3 micrometers. As discussed above, the immersion tin plating prevents oxidation of the conductive material of the leads for an amount of time based on the thickness of the immersion tin plating. For example, the immersion tin plating is applied to have a thickness sufficient to prevent consumption of the copper leads of the flat no-leads IC packages for at least one year.

The plating material is reduced over time due to an oxidation-reduction reaction between the interconnect material and the plating material until the plating material is unable to protect the interconnect material. The thicker the plating material, the longer the plating material protects the interconnect material thereby increasing the shelf-life of the corresponding flat no-leads IC package. The devices and methods described herein provide thicker immersion plating on the wettable flank of the flat no-leads IC package, which increases the shelf-life and reliability of the flat no-leads IC package.

At 914, a third rinsing cycle is performed.

At 916, the strip undergoes a first dip process and is dipped in a first dip chemical to prepare the strip for a second dip chemical in a first post-dip process. At 918, a fourth rinsing cycle is performed. At 920, the strip undergoes a second post dip process and is dipped in the second dip chemical to prepare the strip for a third dip chemical. At 922, a fifth rinsing cycle is performed.

At 924, the strip undergoes a third dip process and is dipped in third dip chemical that forms an anti-tarnish layer on the immersion tin plating. At 926, a sixth rinsing cycle is performed. At 928, a hot rinse is performed to rinse the strip. At 930, air is applied to the strip and at 932, a drying process is performed.

In this description, unless otherwise stated, “about,” “approximately” or “substantially” preceding a parameter means being within +/−10 percent of that parameter. Modifications are possible in the described embodiments, and other embodiments are possible, within the scope of the claims.

What is claimed is:

1. A method for forming integrated circuit (IC) packages, the method comprising:
mounting tape on a mold compound of a strip of flat no-leads IC packages;
sawing the mold compound of the strip of flat no-leads IC packages to form singulated IC packages mounted on the tape; and
immersing the singulated IC packages in a bath of immersion tin to form immersion tin plating on a flank of leads of the singulated IC packages.

2. The method of claim 1, wherein the immersion tin plating has a thickness greater than 2 micrometers.

3. The method of claim 1, wherein the immersion tin plating has a thickness greater than 3 micrometers.

4. The method of claim 1, wherein the immersion tin plating has a height of at least 50 micrometers.

5. The method of claim 1, wherein the bath of immersion tin is formed with a solution of tin, tin salt and an activator.

6. The method of claim 1, wherein the singulated IC packages of the strip of flat no-leads IC packages have copper interconnects.

7. The method of claim 6, wherein the immersing comprises:
etching exposed copper of the copper interconnects; and
dipping the singulated IC packages in the bath of immersion tin such that the etched exposed copper is submerged in the immersion tin.

8. The method of claim 7, further comprising:
rinsing the singulated IC packages before and after the dipping.

9. The method of claim 8, further comprising:
rinsing the singulated IC packages before and after the etching.

10. The method of claim 7, wherein the immersing further comprises shocking the bath of tin in response to the dipping.

11. The method of claim 10, wherein immersing further comprises vibrating the bath of tin during the dipping.

12. The method of claim 7, further comprising encapsulating the strip of flat no-leads IC packages in the mold compound, wherein a bottom and the flank of the leads are exposed.

13. The method of claim 12, further comprising, applying matted tin plating to the bottom of leads of the strip of flat no-leads IC packages prior to the dipping.

14. The method of claim 13, wherein the immersion tin of the bath of immersion tin is non-reactive to the matted tin plating.

15. An integrated circuit (IC) package comprising:
a die mounted on a flat no-leads interconnect; and
a mold compound encapsulating the die on a top side of the flat no-leads interconnect, wherein a flank of leads of the flat no-leads interconnect have an immersion tin plating that is greater than 2 micrometers thick.

16. The IC package of claim 15, wherein the leads of the flat no-leads interconnect are formed with copper.

17. The IC package of claim 16, wherein the immersion tin plating has a thickness greater than 3 micrometers.

18. The IC package of claim 16, wherein the immersion tin plating has a thickness sufficient to prevent consumption by the copper leads of the flat no-leads interconnect for at least 1 year.

19. The IC package of claim 15, wherein a bottom side of the leads of the IC package has matted tin plating.

20. The IC package of claim 15, wherein the immersion tin plating is at least 50 micrometers in height.
